(19) United States
(12) Patent Application Publication
(10) Pub. No.: US 2019/0115476 A1
(43) Pub. Date: Apr. 18, 2019

(54) TRANSISTOR, DISPLAY UNIT, AND ELECTRONIC APPARATUS

(71) Applicant: JOLED INC., Tokyo (JP)

(72) Inventor: Yoshihiro OSHIMA, Tokyo (JP)

(21) Appl. No.: 16/213,715

(22) Filed: Dec. 7, 2018

Related U.S. Application Data
(62) Division of application No. 15/404,783, filed on Jan. 12, 2017.
Application No. 15/404,783 is a continuation of application No. PCT/JP2015/064345, filed on May 19, 2015.

(30) Foreign Application Priority Data
Jul. 16, 2014 (JP) 2014-145809

(51) Int. Cl. H01L 29/786; H01L 27/12; G09F 9/30; H01L 29/66; H01L 29/423; G02F 1/1368; H01L 21/28

(52) U.S. Cl. CPC H01L 29/78621; H01L 27/1225; H01L 29/78696; G09F 9/30; H01L 27/3262; H01L 29/42384; H01L 29/7869; G02F 1/1368; H01L 21/28; H01L 29/66969

(57) ABSTRACT

A transistor includes a gate electrode, an oxide semiconductor film, and a gate insulating film. The oxide semiconductor film includes a channel region and a low-resistance region. The channel region faces the gate electrode. The low-resistance region has a resistance value lower than a resistance value of the channel region. The gate insulating film is provided between the oxide semiconductor film and the gate electrode, and has a first surface located closer to the oxide semiconductor film and a second surface located closer to the gate electrode. The first surface of the gate insulating film has a length in a channel length direction which is greater than a maximum length of the gate electrode in the channel length direction.

### CROSS REFERENCE TO RELATED APPLICATIONS

This is a Divisional application of U.S. patent application Ser. No. 15/404,783, filed on Jan. 12, 2017, which is a Continuation of International Application No. PCT/JP2015/064345, filed May 19, 2015, which claims the benefit of Japanese Priority Patent Application JP2014-145809, filed Jul. 16, 2014 the entire contents of which are incorporated herein by reference.

### BACKGROUND

The disclosure relates to a transistor using an oxide semiconductor film, and a display unit and an electronic apparatus including the transistor.

Active drive system liquid crystal display units and organic electroluminescence (EL) display units use a thin film transistor (TFT) as a driving device. Recently, along with larger-sized displays and higher-speed driving of the display, there have been increasingly higher requirements for the characteristics of the thin film transistors. Use of oxide semiconductors such as zinc oxide (ZnO) and indium-gallium-zinc oxide (IGZO) for the thin film transistor enables high mobility to be obtained and also larger size to be obtained. Therefore, developments of the thin film transistors using oxide semiconductors have been vigorously implemented (for example, see Japanese Unexamined Patent Application Publication No. 2012-33836).

For obtaining the higher-speed of the display, it is desirable to increase a current amount that is able to be flowed to the thin film transistor, i.e., to enhance the mobility, as well as to reduce a parasitic capacitance that occurs in the thin film transistor. The reduction in the parasitic capacitance that occurs in the thin film transistor enables prevention of delay of signals, for example.

For example, N. Morosawa et al, Journal of SID, Vol. 20, Issue 1, 2012, pp. 47-52 discloses a top gate thin film transistor having a self-aligning structure. In the thin film transistor, a gate electrode and a gate insulating film are provided at the same position in a plan view on a channel region of an oxide semiconductor film, and thereafter a region exposed from the gate electrode and the gate insulating film of the oxide semiconductor film is allowed to have lower resistance to form a source/drain region (low-resistance region). For example, the low-resistance region of the oxide semiconductor film contains aluminum (AI). In such a thin film transistor having the self-aligning structure, a parasitic capacitance formed in a cross region between the gate electrode and the source/drain electrode is suppressed.

### SUMMARY

However, due to a step such as an annealing step that is performed in producing a thin film transistor, for example, an element such as aluminum is diffused to a portion (diffusion region) other than a low-resistance region. In the diffusion region, the resistance value of the oxide semiconductor film is lowered. Accordingly, when the diffusion region is formed at a position overlapped with a gate electrode in a plan view, i.e., in a portion of a channel region, a parasitic capacitance occurs between the gate electrode and the diffusion region.

It is desirable to provide a transistor, a display unit, and an electronic apparatus that make it possible to reduce the parasitic capacitance.

A first transistor according to an embodiment of the technology includes a gate electrode, an oxide semiconductor film, and a gate insulating film. The oxide semiconductor film includes a channel region and a low-resistance region. The channel region faces the gate electrode. The low-resistance region has a resistance value lower than a resistance value of the channel region. The gate insulating film is provided between the oxide semiconductor film and the gate electrode, and has a first surface located closer to the oxide semiconductor film and a second surface located closer to the gate electrode. The first surface of the gate insulating film has a length in a channel length direction which is greater than a maximum length of the gate electrode in the channel length direction.

A display unit according to an embodiment of the technology includes a display device and a transistor that drives the display device, and uses, as the transistor, the first transistor according to an embodiment of the technology described above. The transistor includes a gate electrode, an oxide semiconductor film, and a gate insulating film. The oxide semiconductor film includes a channel region and a low-resistance region. The channel region faces the gate electrode. The low-resistance region has a resistance value lower than a resistance value of the channel region. The gate insulating film is provided between the oxide semiconductor film and the gate electrode, and has a first surface located closer to the oxide semiconductor film and a second surface located closer to the gate electrode. The first surface of the gate insulating film has a length in a channel length direction which is greater than a maximum length of the gate electrode in the channel length direction.

An electronic apparatus according to an embodiment of the technology includes the display unit according to an embodiment of the technology described above. The display unit includes a display device and a transistor that drives the display device. The transistor includes a gate electrode, an oxide semiconductor film, and a gate insulating film. The oxide semiconductor film includes a channel region and a low-resistance region. The channel region faces the gate electrode. The low-resistance region has a resistance value lower than a resistance value of the channel region. The gate insulating film is provided between the oxide semiconductor film and the gate electrode, and has a first surface located closer to the oxide semiconductor film and a second surface located closer to the gate electrode. The first surface of the gate insulating film has a length in a channel length direction which is greater than a maximum length of the gate electrode in the channel length direction.

In the first transistor, the display unit, or the electronic apparatus according to an embodiment of the technology, a length of the first surface of the gate insulating film in the channel length direction is greater than the maximum length of the gate electrode in the channel length direction, and thus the channel region and the low-resistance region are provided apart from each other. Accordingly, even when being diffused in the oxide semiconductor film, an element such as aluminum in the low-resistance region is less likely to reach the channel region.

A second transistor according to an embodiment of the technology includes a gate electrode, and an oxide semiconductor film including a channel region that faces the gate electrode and a low-resistance region that is provided apart from the channel region and has a resistance value lower than a resistance value of the channel region.

In the second transistor according to an embodiment of the technology, the low-resistance region is provided apart from the channel region, and thus an element such as aluminum in the low-resistance region is less likely to reach the channel region.

According to the first transistor, the display unit, and the electronic apparatus of an embodiment of the technology, the length of the first surface of the gate insulating film in the channel length direction is configured to be greater than the maximum length of the gate electrode in the channel length direction. In addition, according to the second transistor of an embodiment of the technology, the low-resistance region of the oxide semiconductor film is configured to be provided apart from the channel region. Thus, it becomes possible to prevent the channel region from having lower resistance. This enables reduction in a parasitic capacitance. Note that the effects described herein are non-limiting, and may be any effects described in the present disclosure.

### BRIEF DESCRIPTION OF THE DRAWINGS

FIG. 1 is a cross-sectional view of a configuration of a transistor according to a first embodiment of the technology.

FIG. 2 illustrates a planar configuration of a gate insulating film illustrated in FIG. 1.

FIG. 3A is a cross-sectional view of one step of a process for manufacturing the transistor illustrated in FIG. 1.

FIG. 3B is a cross-sectional view of a step subsequent to FIG. 3A.

FIG. 3C is a cross-sectional view of a step subsequent to FIG. 3B.

FIG. 4A is a cross-sectional view of a step subsequent to FIG. 3C.

FIG. 4B is a cross-sectional view of a step subsequent to FIG. 4A.

FIG. 4C is a cross-sectional view of a step subsequent to FIG. 4B.

FIG. 5A is a cross-sectional view of a step subsequent to FIG. 4C.

FIG. 5B is a cross-sectional view of a step subsequent to FIG. 5A.

FIG. 5C is a cross-sectional view of a step subsequent to FIG. 5B.

FIG. 6 is a cross-sectional view of a configuration of a semiconductor device according to a comparative example.

FIG. 7 is a cross-sectional view of a configuration of a transistor according to Modification Example 1.

FIG. 8 is a cross-sectional view of a configuration of a transistor according to Modification Example 2.

FIG. 9 is a cross-sectional view of a configuration of a transistor according to Modification Example 3.

FIG. 10 is a cross-sectional view of a configuration of a transistor according to a second embodiment of the technology.

FIG. 11 is a cross-sectional view of an example of a configuration of a display unit including the transistor illustrated in FIG. 1.

FIG. 12 illustrates an overall configuration of the display unit illustrated in FIG. 11.

FIG. 13 illustrates an example of a circuit configuration of a pixel illustrated in FIG. 12.

FIG. 14 is a cross-sectional view of another example of the display unit illustrated in FIG. 11.

FIG. 15 is a cross-sectional view of yet another example of the display unit illustrated in FIG. 11.

FIG. 16 is a perspective view of an application example of the display unit illustrated in FIG. 11.

### DETAILED DESCRIPTION

Some embodiments of the technology are described in detail below with reference to drawings. Note that description will be given in the following order.

1. First Embodiment (a transistor: an example of a transistor having a top gate structure)
2. Modification Example 1 (an example in which a gate electrode and a gate insulating film have a tapered shape)
3. Modification Example 2 (an example of having a gate insulating film with a rectangular cross-sectional shape)
4. Modification Example 3 (an example of having a gate insulating film with a laminate structure)
5. Second Embodiment (a transistor: an example of a transistor having a bottom gate structure)
6. Application Example (display unit)

### First Embodiment

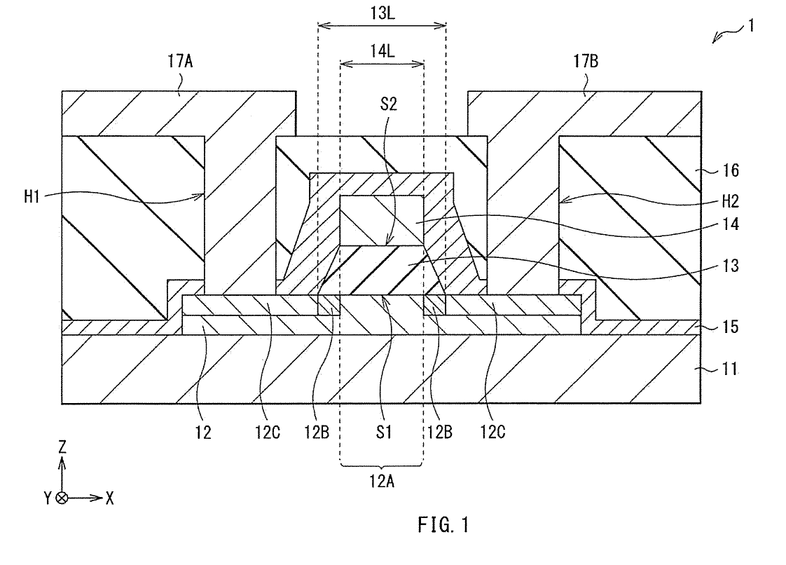

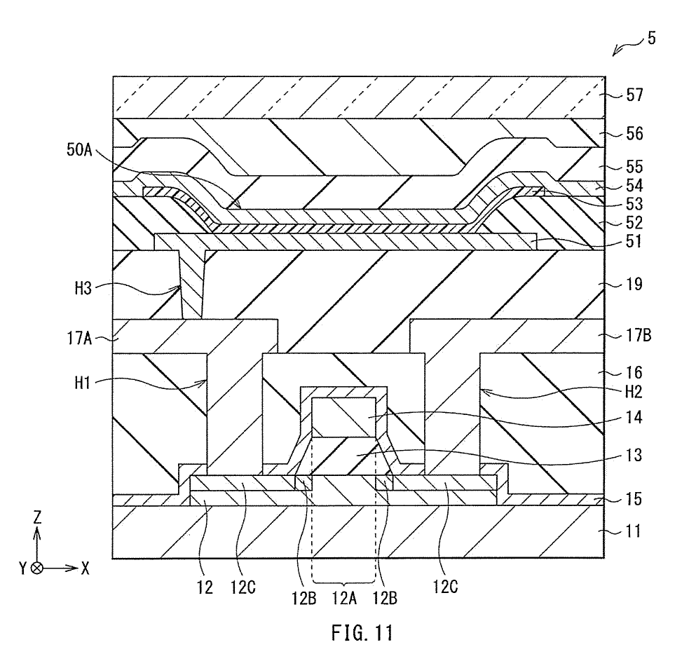

FIG. 1 illustrates a cross-sectional configuration of a transistor (a transistor 1) according to a first embodiment of the technology. The transistor 1 includes an oxide semiconductor film 12 provided on a substrate 11. The transistor 1 may have a staggered structure (a top gate structure). A gate insulating film 13 and a gate electrode 14 are disposed in this order in a selective region on the oxide semiconductor film 12. A high-resistance film 15 and an interlayer insulating film 16 may be provided to cover the oxide semiconductor film 12, the gate insulating film 13, and the gate electrode 14. A source/drain electrodes 17A and 17B may be provided on the interlayer insulating film 16. The high-resistance film 15 and the interlayer insulating film 16 may have connection holes H1 and H2 to penetrate therethrough. The source/drain electrode 17A and the source/drain electrode 17B may be electrically coupled to a low-resistance region 12C described later of the oxide semiconductor film 12 through the connection hole H1 and the connection hole H2, respectively. The staggered-structured transistor 1 including the TFT allows the oxide semiconductor film 12 to be directly formed on the substrate 11, and the oxide semiconductor film 12 may be covered with the gate electrode 14. Thus, it is possible to protect the oxide semiconductor film 12 from an upper layer such as an organic layer (an organic layer 53 in FIG. 11 described later) including a light-emitting layer, for example. Therefore, it is possible for the transistor 1 to be suitably used as a display driving device.

The substrate 11 may be made of a plate material such as quartz, glass, silicon, and a resin (plastic) film. An inexpensive resin film may be used owing to the oxide semiconductor film 12 which is formed without heating the substrate 11 in a sputtering method described later. Examples of the resin material may include polyethylene terephthalate (PET), polyimide (PI), polycarbonate (PC), and polyethylene naphthalate (PEN). A barrier film such as a silicon oxide film (SiOx), a silicon nitride film (SiNx), and an aluminum oxide film (AlOx) may also be provided on the substrate 11 made of the resin material. The barrier film may also be a laminate film. Other than these materials, it is also possible to use a metal substrate such as stainless steel (SUS) with an insulating material formed thereon depending on purposes.

The oxide semiconductor film 12 may be provided in a selective region on the substrate 11, and may have a function as an active layer of the TFT. The oxide semiconductor film 12 may contain, as a main component, an oxide of one or more elements of indium (In), gallium (Ga), zinc (Zn), tin (Sn), titanium (Ti), and niobium (Nb), for example. More specifically, examples of an amorphous oxide may include indium-tin-zinc oxide (ITZO) and indium-gallium-zinc oxide (IGZO: InGaZnO). Examples of a crystalline oxide may include zinc oxide (ZnO), indium-zinc oxide (IZO (registered trademark)), indium-gallium oxide (IGO), indium-tin oxide (ITO), and indium oxide (InO). It is preferable to use the oxide semiconductor film 12 containing indium. Either an amorphous or crystalline oxide semiconductor material may be used; however, the crystalline oxide semiconductor material may preferably be used in that it is possible to easily secure etching selectivity with respect to the gate insulating film 13. The oxide semiconductor film 12 may have a thickness (thickness in a laminated direction, hereinafter referred to simply as “thickness”) of about 50 nm, for example.

In the oxide semiconductor film 12, a region that faces the gate electrode 14 and is overlapped with the gate electrode 14 in a plan view may serve as a channel region 12A. On the other hand, a part of a region, of the oxide semiconductor film 12, other than the channel region 12A from a surface (upper surface) in a thickness direction may serve as a diffusion region 12B and the low-resistance region 12C both having a resistance value lower than that of the channel region 12A. The low-resistance region 12C may be formed, for example, by reacting metal such as aluminum (Al) with the oxide semiconductor material to diffuse the metal (dopant). Due to the low-resistance region 12C, the transistor 1 may achieve a self-aligning structure, thus making it possible to reduce a parasitic capacitance formed in a cross region between the gate electrode 14 and the source/drain electrodes 17A and 17B. Further, the low-resistance region 12C may also have a role of stabilizing characteristics of the TFT. The diffusion region 12B may be a region that is generated as a result of diffusion of the metal such as aluminum contained in the low-resistance region 12C, and may be formed at a position adjacent to the low-resistance region 12C and between the low-resistance region 12C and the channel region 12A. The concentration of the metal in the diffusion region 12B may be lower than the concentration of the metal in the low-resistance region 12C, and may become lower gradually toward a position closer to the channel region 12A from a position closer to the low-resistance region 12C. The resistance value of the diffusion region 12B may be lower than the resistance value of the channel region 12A, and may be higher than the resistance value of the low-resistance region 12C. As described later in detail, in the transistor 1, the low-resistance region 12C may be provided apart from the channel region 12A, and the diffusion region 12B may be formed toward the channel region 12A from the low-resistance region 12C. The diffusion region 12 B may not be overlapped with the gate electrode 14 in a plan view, and may be provided at a position overlapped with a lower surface (a lower surface S1 described later) of the gate insulating film 13.

The gate insulating film 13 may be provided between the oxide semiconductor film 12 and the gate electrode 14, and may have the lower surface S1 closer to the oxide semiconductor film 12 and an upper surface S2 closer to the gate electrode 14. For example, the lower surface S1 and the upper surface S2 of the gate insulating film 13 may be in contact, respectively, with the oxide semiconductor film 12 and the gate electrode 14. In the present embodiment, a length of the lower surface S1 (a length 13L) of the gate insulating film 13 in the channel length direction (X-direction) is greater than the maximum length of the gate electrode 14 (a length 14L) in the channel length direction. This allows the low-resistance region 12C of the oxide semiconductor film 12 to be formed apart from the channel region 12A as described later in detail, so that metal such as aluminum contained in the low-resistance region 12C is less likely to reach the channel region 12A.

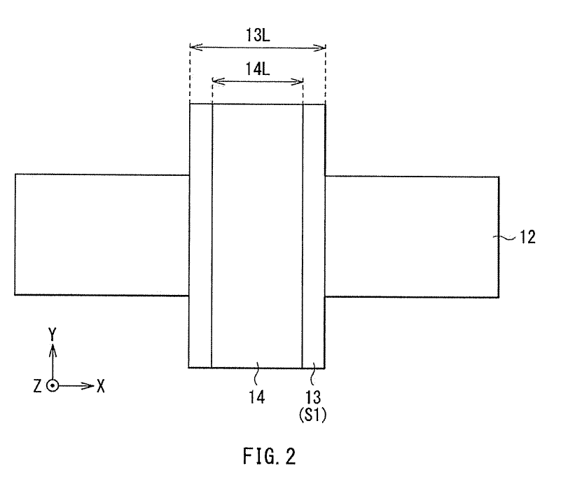

FIG. 2 illustrates a planar configuration of the gate insulating film 13 together with the oxide semiconductor film 12 and the gate electrode 14. The lower surface S1 of the gate insulating film 13 may be expanded in width toward both sides of the gate electrode 14 (toward the source/drain electrodes 17A and 17B) in a plan view. The length 14L of the gate electrode 14 may be, for example, about 3 μm to 100 μm, and may be preferably adjusted by about 4 μm to 16 μm depending on a necessary current amount. The length 13L of the gate insulating film 13 may be, for example, about 0.2 μm to 4 μm greater than the length 14L of the gate electrode 14. In detail, the gate insulating film 13 may be expanded in width by about 0.1 μm to 2 μm toward each of the source/drain electrode 17A and the source/drain electrode 17B, compared to the gate electrode 14. The difference between the length 14L of the gate electrode 14 and the length 13L of the gate insulating film 13 may determine a distance of a gap between the channel region 12A and the low-resistance region 12C of the oxide semiconductor film 12 (FIG. 1). The length of the gate insulating film 13 in a channel width direction (Y-direction) may be equal to the length of the gate electrode 14 in the channel width direction, for example.

The gate insulating film 13 may have a tapered shape, for example, and the cross-sectional shape of the gate insulating film 13 may be a trapezoidal shape. In other words, the length of the upper surface S2 of the gate insulating film 13 in the channel length direction may be smaller than the length 13L, and may be equal to the length 14L of the gate electrode 14, for example.

Such a gate insulating film 13 may be configured by, for example, a monolayer film made of one of a silicon oxide film (SiOx), a silicon nitride film (SiNx), a silicon oxynitride film (SiON), and aluminum oxide film (AlOx), or by a laminate film made of two or more of the monolayer films. Among those oxide films, the silicon oxide film and the aluminum oxide film may be preferable in that these oxide films are less likely to reduce the oxide semiconductor. The thickness of the gate insulating film 13 may be 300 nm, for example.

The gate electrode 14 controls the density of carriers in the oxide semiconductor film 12 with a gate voltage (Vg) to be applied to the TFT, and may have a function as wiring that supplies a potential. The cross-sectional shape of the gate electrode 14 may be, for example, a rectangular shape, and the lower surface and the upper surface of the gate electrode 14 may have substantially the same planar shape as each other. In other words, the maximum length 14L of the gate electrode 14 in the channel length direction may be the length of each of the lower surface and the upper surface of the gate electrode 14 in the channel length direction. The gate electrode 14 may be, for example, a simple substance made of one of molybdenum (Mo), titanium (Ti), aluminum, silver (Ag), neodymium (Nd), and copper (Cu) or an alloy thereof, or a laminate film made of two or more of the simple substances or alloy. Specific examples may include a laminate structure in which low-resistance metal such as aluminum and silver is interposed by molybdenum or titanium, and an alloy of aluminum and neodymium (Al—Nd alloy). A material having resistance to wet etching may be used at a position close to the gate insulating film 13, and a material that is processable with a selective etching solution having selectivity with respect to the gate insulating film 13 may be laminated on the material having resistance to wet etching, so that the gate electrode 14 may be preferably configured. It is possible to use, as the gate electrode 14, for example, a laminate film in which titanium, aluminum, and molybdenum may be laminated in this order from a position close to the gate insulating film 13. The gate electrode 14 may also be configured by a transparent electrically-conductive film such as ITO. The thickness of the gate electrode 14 may be, for example, 10 nm to 500 nm.

The high-resistance film 15 may be a residue of a metal film, as an oxide film, which is a supply source of metal that is diffused to the low-resistance region 12C of the oxide semiconductor film 12 in a manufacturing step described later. The high-resistance film 15 may have a thickness of equal to or smaller than 20 nm, for example, and may be made of titanium oxide, aluminum oxide, indium oxide, or tin oxide, for example. Such a high-resistance film 15 may have a favorable barrier property to the outside air, and thus may also have a function of reducing the influence of oxygen or moisture that may change electrical characteristics of the oxide semiconductor film 12 in the transistor 1, in addition to the above-described role in the processes. Providing the high-resistance film 15 enables stabilization of electrical characteristics of the transistor 1, thus making it possible to further enhance the effects of the interlayer insulating film 16.

In order to enhance the barrier function, for example, a protective film having a thickness of about 30 nm to 50 nm made of aluminum oxide or silicon nitride may be laminated on the high-resistance film 15. This further stabilizes the electrical characteristics of the oxide semiconductor film 12 in the transistor 1.

The interlayer insulating film 16 may be laminated on the high-resistance film 15, and may be made of an organic material such as an acrylic resin, polyimide, a novolac resin, a phenol resin, an epoxy resin and a vinyl chloride resin. An inorganic material such as a silicon oxide film, a silicon nitride film, a silicon oxynitride film, and aluminum oxide may also be used for the interlayer insulating film 16. Alternatively, the organic material and the inorganic material may also be laminated for use. The thickness of the interlayer insulating film 16 containing the organic material may be easily increased to a thickness of about 1 μm to 2 μm, for example. The interlayer insulating film 16 having a thickness that is thus increased is able to sufficiently coat a step formed after the processing of the gate electrode 14 to secure an insulation property. The interlayer insulating film 16 in which the silicon oxide film and the aluminum oxide film are laminated is able to prevent entry of moisture and diffusing into the oxide semiconductor film 12. This not only stabilizes the electrical characteristics of the transistor 1 but also enhances reliability.

The source/drain electrodes 17A and 17B may each have a thickness of about 200 nm, for example, and may be configured by a metal or transparent electrically-conductive film similar to those listed for the above-described gate electrode 14. The source/drain electrodes 17A and 17B may be preferably made of, for example, the low-resistance metal such as aluminum and copper, and may be more preferably a laminate film in which such a low-resistance metal is interposed between barrier layers each made of titanium or molybdenum. Use of such a laminate film enables driving with less wiring delay. Further, it is desirable that the source/drain electrodes 17A and 17B be so provided as to avoid at a region immediately above the gate electrode 14, in order to prevent formation of a parasitic capacitance in the cross region between the gate electrode 14 and the source/drain electrodes 17A and 17B.

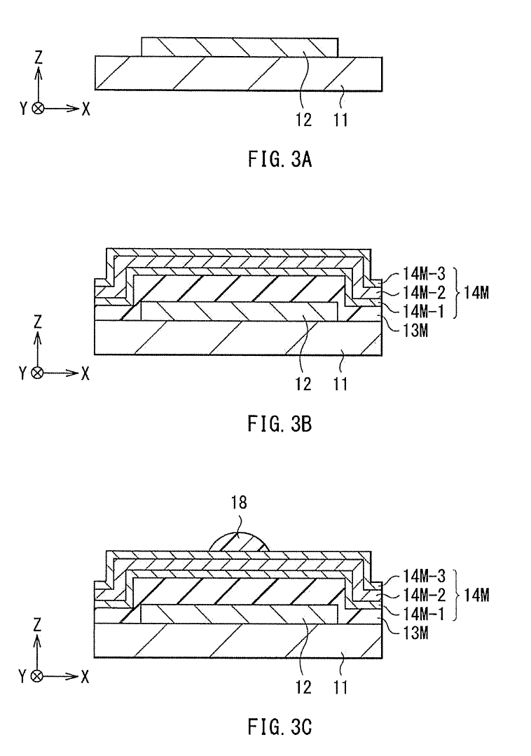

The transistor 1 is manufactured, for example, as follows (FIGS. 3A to 5C).

First, as illustrated in FIG. 3A, the oxide semiconductor film 12 made of the above-described material may be formed on the substrate 11. More specifically, an oxide semiconductor material film (not illustrated) may be first formed to have a thickness of about 50 nm, for example, throughout the entire surface of the substrate 11 by means of a sputtering method, for example. In this case, a ceramic having the same composition as that of the oxide semiconductor to be formed may be used as a target. Further, the concentration of carriers in the oxide semiconductor may largely depend on oxygen partial pressure in sputtering, and thus the oxygen partial pressure may be controlled so as to obtain desired transistor characteristics. The oxide semiconductor material film may also be formed by means of methods such as an electron beam evaporation method, a pulsed laser deposition (PLD) method, an ion plating method, and a sol-gel method. The oxide semiconductor film 12 made of the above-described crystalline material makes it possible to easily enhance etching selectivity in a step of etching the gate insulating film 13 to be described later. Thereafter, photolithography and etching may be used, for example, to pattern the formed oxide semiconductor film into a predetermined shape. In this case, a wet etching using a mixed solution of phosphoric acid, nitric acid, and acetic acid may be preferably adopted for processing. The mixed solution of phosphoric acid, nitric acid, and acetic acid enables selectivity with respect to an underlayer to be sufficiently large, thus allowing for relatively easy processing.

After providing the oxide semiconductor film 12, an insulating material film 13M made of a silicon oxide film or an aluminum oxide film having a thickness of 100 nm, for example, may be formed throughout the entire surface of the substrate 11. The insulating material film 13M may be provided for forming the gate insulating film 13. For formation of the insulating material film 13M, it is possible to use a plasma chemical vapor deposition (CVD) method, for example. It is also possible to use a reactive sputtering method, besides the plasma CVD method, to form the silicon oxide film. Further, when forming the aluminum oxide film, it is also possible to use an atomic layer deposition (ALD) method, in addition to the reactive sputtering method and the CVD method.

Next, an electrically-conductive material film 14M may be formed on the insulating material film 13M (FIG. 3B). The electrically-conductive material film 14M may be provided for forming the gate electrode 14. The electrically-conductive material film 14M may have a configuration in which an electrically-conductive film 14M-1 made of titanium, an electrically-conductive film 14M-2 made of aluminum, and an electrically-conductive film 14M-3 made of molybdenum are laminated in this order, for example, from a position close to the gate insulating film 13. The electrically-conductive material film 14M may be formed using methods such as the sputtering method, a thermal deposition method, and an electron beam deposition method.

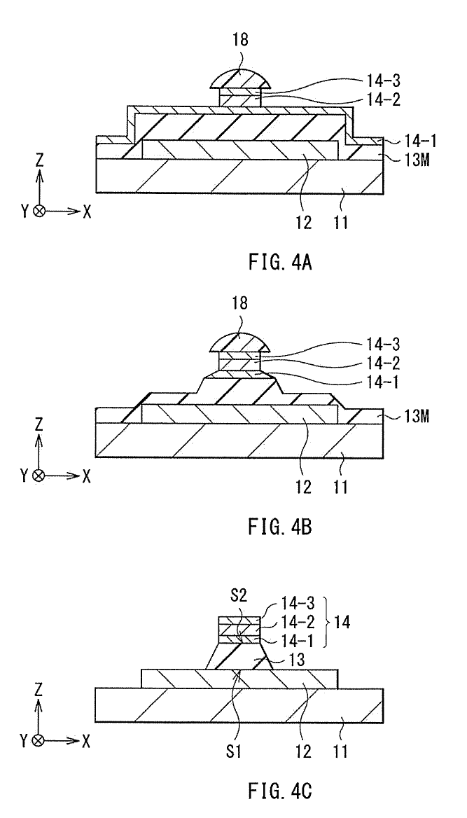

After formation of the electrically-conductive material film 14M, a resist pattern 18 may be formed in a selective region (a region on which the gate electrode 14 is formed) on the electrically-conductive material film 14M (electrically-conductive film 14M-3) as illustrated in FIG. 3C. Next, wet etching of the electrically-conductive films 14-M2 and 14M-3 may be performed using the resist pattern 18 as a mask (FIG. 4A). At this time, side etching may occur in the wet etching step. A portion that has undergone the side etching (critical dimension (CD) loss) may be controlled to have a proper size to allow the resist pattern 18 to cover the electrically-conductive films 14-2 and 14-3 in an eave shape after the wet etching. More specifically, a length of the resist pattern 18 in the channel length direction is designed to be greater than a length of each of the electrically-conductive films 14-2 and 14-3 8 in the channel length direction after the wet etching.

After the wet etching of the electrically-conductive films 14-M2 and 14M-3 is performed, dry etching of the electrically-conductive films 14-M1 and the insulating material film 13M may be performed, for example (FIG. 4B). In this step, dry etching bias may be controlled to thereby first allow the electrically-conductive film 14-M1 located below the eave-shaped resist pattern 18 to be processed into a tapered shape, and to allow the insulating material film 13M to be gradually processed while the tapered electrically-conductive film 14-M1 functions as a mask. This may form the gate electrode 14 including the electrically-conductive films 14-1, 14-2, and 14-3, and the tapered gate insulating film 13. After the formation of the gate electrode 14, and the tapered gate insulating film 13, the resist pattern 18 may be removed (FIG. 4C).

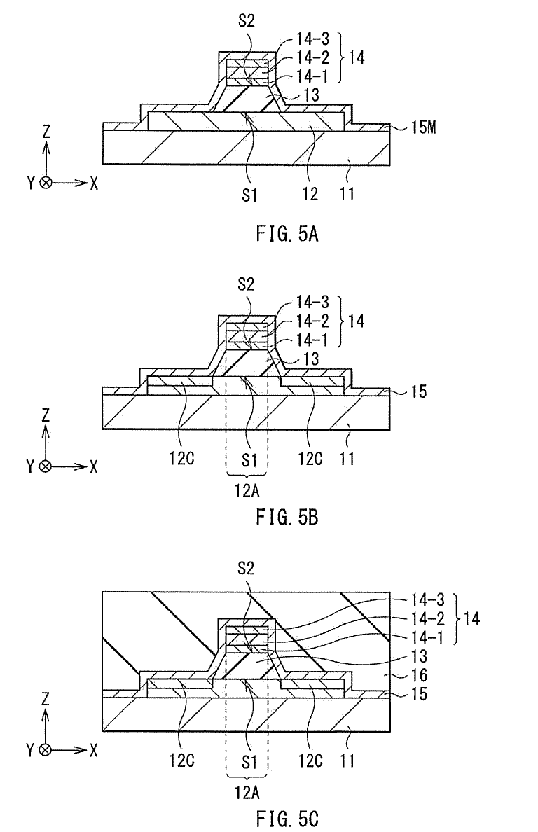

Subsequently, as illustrated in FIG. 5, a metal film 15M made of, for example, titanium, aluminum, tin, or indium may be formed throughout the entire surface on the substrate 11 to allow the metal film 15M to have a thickness of, for example, equal to or greater than 5 nm and equal to or smaller than 10 nm by means of, for example, the sputtering method or an atomic layer deposition method.

Next, a thermal treatment may be performed, for example, at a temperature of about 300° C. to thereby oxidize the metal film 15M, thus forming the high-resistance film 15 as illustrated in FIG. 5B. At this time, the low-resistance region 12C may be formed at a portion, of the oxide semiconductor film 12, which is in contact with the high-resistance film 15. In other words, the low-resistance region 12C may be formed at a portion except a region, of the oxide semiconductor film 12, on which the lower surface S1 of the gate insulating film 13 is provided. The low-resistance region 12C may be provided, for example, in a part of the oxide semiconductor film 12 (closer to the high-resistance film 15) in the thickness direction. An oxidation reaction of the metal film 15M utilizes a part of oxygen contained in the oxide semiconductor film 12. Therefore, along with progress of the oxidation of the metal film 15M, oxygen concentration in the oxide semiconductor film 12 may be lowered from the surface (upper surface) in contact with the metal film 15M. On the other hand, metal such as aluminum may be diffused into the oxide semiconductor film 12 from the metal film 15M. The metal element may function as a dopant, thus lowering resistance of a region on the upper surface side, of the oxide semiconductor film 12, which is in contact with the metal film 15. This may form the low-resistance region 12C having lower electrical resistance than that of the channel region 12A in a self-aligning manner.

Annealing at a temperature of about 300° C. as described above may be preferable as the thermal treatment of the metal film 15M. In this case, annealing in an oxidative gaseous atmosphere containing, for example, oxygen may prevent the oxygen concentration in the low-resistance region 12C from being lowered too much, thus enabling sufficient supply of oxygen to the oxide semiconductor film 12. This makes it possible to eliminate annealing steps to be performed in subsequent steps, thereby simplifying the steps.

A temperature of the substrate 11 in forming the metal film 15M on the substrate 11 may also be set relatively high, for example, instead of performing the above-described annealing step, thereby forming the high-resistance film 15. In the step of FIG. 5A, for example, when the metal film 15M is formed while keeping the temperature of the substrate 11 at about 300° C., it becomes possible to lower resistance of a predetermined region of the oxide semiconductor film 12 without performing the thermal treatment. In this case, it is possible to reduce the concentration of carriers in the oxide semiconductor film 12 to a level necessary for the transistor.

The metal film 15M may be preferably formed to have a thickness of equal to or smaller than 10 nm as described above. This is because the metal film 15M having a thickness of equal to or smaller than 10 nm enables complete oxidation of the metal film 15M (formation of the high-resistance film 15) by means of the thermal treatment. When the metal film 15M is not completely oxidized, it is desirable to have a step of removing the unoxidized metal film 15M by means of etching. When the metal film 15M that is not sufficiently oxidized remains, for example, on the gate electrode 14, there is a possibility of occurrence of a leak current. When the metal film 15M is completely oxidized to form the high-resistance film 15, such a removing step may become unnecessary, thus allowing for simplification of the manufacturing step. In other words, it becomes possible to prevent the occurrence of the leak current even without performing the removing step by means of etching. Note that, when the metal film 15M is formed to have a thickness of equal to or smaller than 10 nm, the high-resistance film 15 after the thermal treatment may have a thickness of about equal to or smaller than 20 nm.

It is also possible to use methods such as oxidation in a steam atmosphere and plasma oxidation, besides the above-described thermal treatment, as a method of oxidizing the metal film 15M. Particularly the case of the plasma oxidation may have the following advantage. After formation of the high-resistance film 15, the interlayer insulating film 16 may be formed by means of the plasma CVD method; the interlayer insulating film 16 may be formed subsequently (continuously) after the plasma oxidation treatment is performed for the metal film 15M. Therefore, there is an advantage in that it is not necessary to increase a process. As for the plasma oxidation, a treatment may be desirably performed such that, for example, the temperature of the substrate 11 is set to about 200° C. to 400° C., and plasma may be generated in a gaseous atmosphere containing oxygen, such as in a mixed gas of oxygen and oxygen dinitride. This is because such a treatment makes it possible to form the above-described high-resistance film 15 having a favorable barrier property to the outside air.

After the formation of the high-resistance film 15, the interlayer insulating film 16 may be formed throughout the entire surface on the high-resistance film 15 as illustrated in FIG. 5C. When the interlayer insulating film 16 includes an inorganic insulating material, for example, the plasma CVD method, the sputtering method, or the atomic layer deposition method may be used. When the interlayer insulating film 16 includes an organic insulating material, for example, a coating method such as a spin coating method and a slit coating method may be used. The coating method allows for easy formation of the interlayer insulating film 16 having an increased thickness. When forming the interlayer insulating film 16 with aluminum oxide, it is possible to use the reactive sputtering method adopting aluminum, for example, as a target by means of a direct current (DC) or alternating current (AC) power supply. After the interlayer insulating film 16 is provided, photolithography and etching may be performed to form the connection holes H1 and H2 at predetermined positions in the interlayer insulating film 16 and the high-resistance film 15.

Subsequently, an electrically-conductive film (not illustrated) made of the material constituting the above-described source/drain electrodes 17A and 17B may be formed on the interlayer insulating film 16 by means of, for example, the sputtering method, and the connection holes H1 and H2 may be filled with the electrically-conductive film. Thereafter, the electrically-conductive film may be patterned by means of, for example, photolithography and etching into a predetermined shape. Thus, the source/drain electrodes 17A and 17B may be formed on the interlayer insulating film 16, and the source/drain electrodes 17A and 17B may be each coupled to the low-resistance region 12C of the oxide semiconductor film 12. Through the foregoing steps, the transistor 1 illustrated in FIG. 1 is completed.

In the transistor 1, when a voltage (a gate voltage) equal to or higher than a threshold voltage is applied to the gate electrode 14, a carrier may flow to the channel region 12A of the oxide semiconductor film 12. This allows a current to flow between the source/drain electrode 17A and the source/drain electrode 17B.

A region in contact with the high-resistance film 15, i.e., the low-resistance region 12C of the oxide semiconductor film 12 may be a region other than a region in contact with the lower surface S1 of the gate insulating film 13. On the other hand, the channel region 12A of the oxide semiconductor film 12 may be a region overlapped with the gate electrode 14 in a plan view. In this example, the length 13L of the lower surface S1 of the gate insulating film 13 in the channel length direction is greater than the maximum length 14L of the gate electrode 14 in the channel length direction. Accordingly, the low-resistance region 12C may be provided apart from the channel region 12A. Therefore, in the transistor 1, metal such as aluminum contained in the low-resistance region 12C is less likely to reach the channel region 12A. This will be described below.

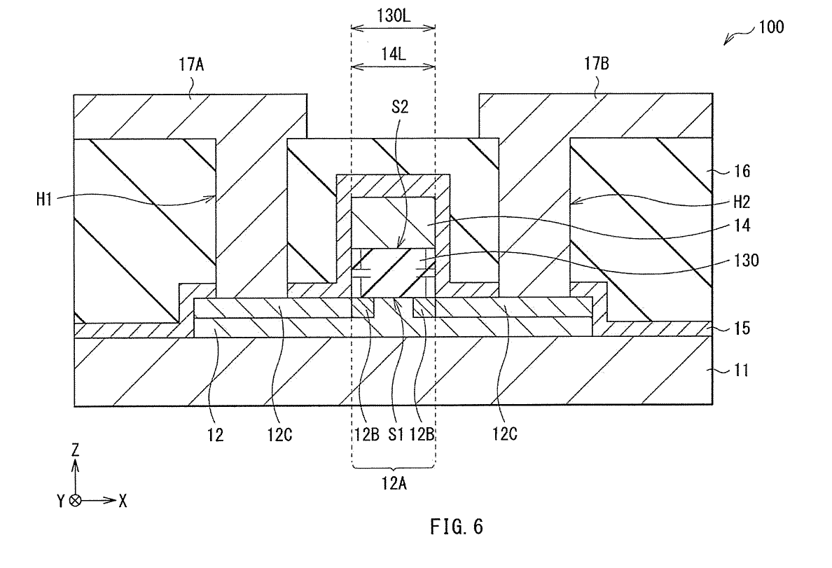

FIG. 6 illustrates a cross-sectional configuration of a transistor (a transistor 100) according to a comparative example. In the transistor 100, a length 130L of the lower surface S1 of a gate insulating film 130 in the channel length direction may be equal to the maximum length 14L of the gate electrode 14 in the channel length direction, and the gate insulating film 130 and a gate electrode 140 may be provided at a position overlapping each other in a plan view. In such a transistor 100, the high-resistance film 15 may be in contact with a region, of the oxide semiconductor film 12, other than the channel region 12A (region, of the oxide semiconductor film 12, overlapped with the gate electrode 14 in a plan view), and thus the low-resistance region 12C may be provided at a position adjacent to the channel region 12A. Accordingly, metal such as aluminum contained in the low-resistance region 12C is more likely to be diffused into the channel region 12A, thus there is a possibility that a part of the channel region 12A may serve as the diffusion region 12B. The metal diffusion length may be, for example, 0.8 μm, but may vary depending on the annealing condition. A parasitic capacitance may occur between the diffusion region 12B formed in a part of the channel region 12A and the gate electrode 14, and may affect the driving speed of a display, for example. Further, when the diffusion region 12B is formed throughout the entire region of the channel region 12A, the transistor 100 may no longer function as a switching device.

In contrast, in the transistor 1, the length 13L of the lower surface S1 of the gate insulating film 13 in the channel length direction is greater than the maximum length 14L of the gate electrode 14 in the channel length direction, and the low-resistance region 12C may be formed apart from the channel region 12A. Accordingly, metal such as aluminum contained in the low-resistance region 12C may be first diffused into a gap between the low-resistance region 12C and the channel region 12A, and is less likely to reach the channel region 12A. In other words, the diffusion region 12B may be provided between the low-resistance region 12C and the channel region 12A, and is less likely to be formed in a part of the channel region 12A. In order for the metal diffusion length not to exceed the distance of the gap between the channel region 12A and the low-resistance region 12C, the length 13L of the gate insulating film 13 may be appropriately adjusted depending on conditions such as the annealing condition. Thus, it is possible to prevent the occurrence of a parasitic capacitance as well as to maintain the function of the transistor 1 as a switching device.

Thus, in the present embodiment, the length 13L of the lower surface S1 of the gate insulating film 13 in the channel length direction is designed to be greater than the maximum length 14L of the gate electrode 14 in the channel length direction. Therefore, it becomes possible to prevent the resistance of the channel region 12A from being lowered, thus allowing for reduction in a parasitic capacitance.

Moreover, the diffusion region 12B between the channel region 12A and the low-resistance region 12C of the oxide semiconductor film 12 may have a resistance value that is lower than a resistance value of the channel region 12A and is higher than a resistance value of the low-resistance region 12C. This allows an electric field generated in a region between the channel region 12A and the low-resistance region 12C to be moderated even when a high voltage is applied between the gate electrode 14 and the low-resistance region 12C (source/drain electrodes 17A and 17B), thus making it possible to enhance the reliability of the transistor 1.

Modification examples of the embodiment and other embodiment are described below. In the following description, the same reference symbol is assigned to a component the same as that in the foregoing embodiment, and description therefor is omitted where appropriate.

### Modification Example 1

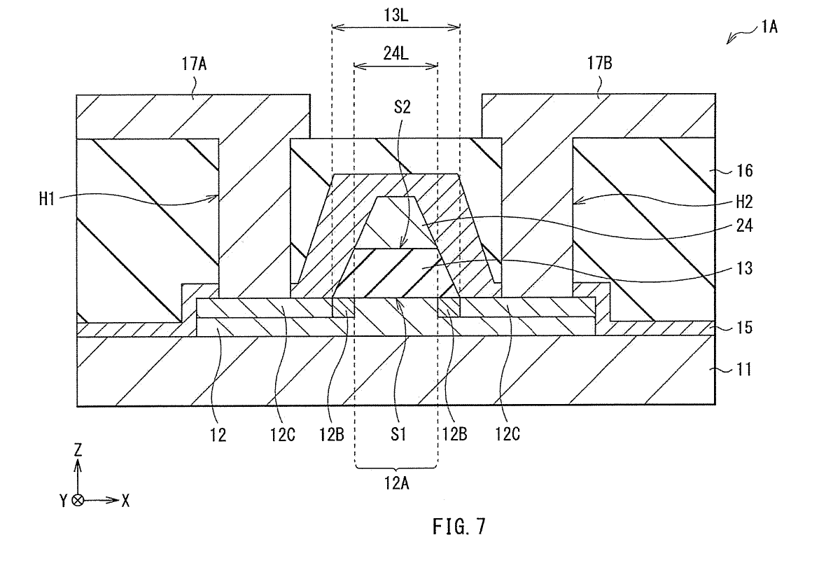

FIG. 7 illustrates a cross-sectional configuration of a transistor (a transistor 1A) according to Modification Example 1 of the foregoing first embodiment. In the transistor 1A, a gate electrode (a gate electrode 24) may have a tapered shape. Except this point, the transistor 1A may have a configuration similar to that of the transistor 1 of the foregoing embodiment, and the function and effect thereof are also similar.

The cross-sectional shape of the gate electrode 24 may be a trapezoidal shape, for example. A maximum length 24L of the gate electrode 24 in the channel length direction may be a length of a lower surface of the gate electrode 24 (a contact surface with respect to the gate insulating film 13) in the channel length direction. In the transistor 1A, the length 13L of the lower surface S1 of the gate insulating film 13 in the channel length direction may be greater than length 24L of the gate electrode 24.

### Modification Example 2

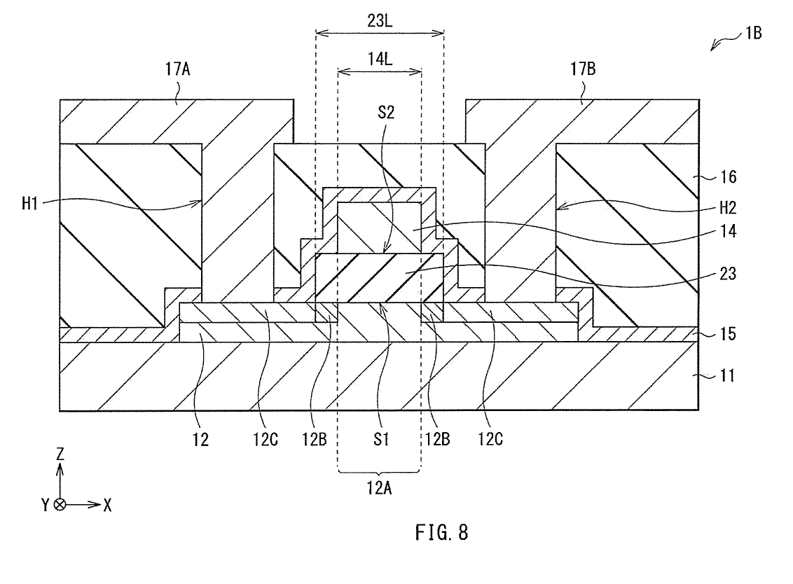

FIG. 8 illustrates a cross-sectional configuration of a transistor (transistor 1B) according to Modification Example 2 of the foregoing first embodiment. A gate insulating film (a gate insulating film 23) of the transistor 1B may have a length of the upper surface S2 in the channel length direction which is equal to a length (a length 23L) of the lower surface S1 in the channel length direction. Except this point, the transistor 1B may have a configuration similar to that of the transistor 1 of the foregoing embodiment, and the function and effect thereof are also similar.

The cross-sectional shape of the gate insulating film 23 may be a rectangular shape, for example. The lower surface S1 and the upper surface S2 of the gate insulating film 23 may be both expanded in width from the gate electrode 14 in a plan view. In the transistor 1B, the length 23L of the lower surface S1 and the upper surface S2 of the gate insulating film 23 in the channel length direction is greater than the maximum length 14L of the gate electrode 14 in the channel length direction. The cross-sectional shape of the gate electrode 14 may be either a rectangular shape (FIG. 8), or a trapezoidal shape (FIG. 7).

Such a transistor 1B is formed, for example, as follows.

Similarly to the transistor 1, the oxide semiconductor film 12 may be first formed on the substrate 11 (FIG. 3A), and thereafter the insulating material film 13M and the electrically-conductive material film 14M may be formed in this order on the oxide semiconductor film 12 (FIG. 3B). Next, the electrically-conductive material film 14M may be patterned by means of photolithography and etching to form the gate electrode 14. Thereafter, the insulating material film 13M may be patterned by means of photolithography and etching to form the gate insulating film 23.

The gate insulating film 23 and the gate electrode 14 may also be formed as follows. The insulating material film 13M may be first formed on the oxide semiconductor film 12, and thereafter the formed insulating material film 13M may be patterned by means of photolithography and etching to form the gate insulating film 23. Next, the electrically-conductive material film 14M may be formed on the gate insulating film 23, and thereafter the formed electrically-conductive material film 14M may be patterned by means of photolithography and etching to form the gate insulating film 14.

After providing the gate insulating film 23 and the gate electrode 14, the transistor 1B is able to be completed using a method similar to that for the transistor 1. In forming the transistor 1B, a material resistant to wet etching may be preferably used for forming the oxide semiconductor film 12, in order to prevent the oxide semiconductor film 12 from being etched as a result of the wet etching for forming the gate electrode 14.

### Modification Example 3

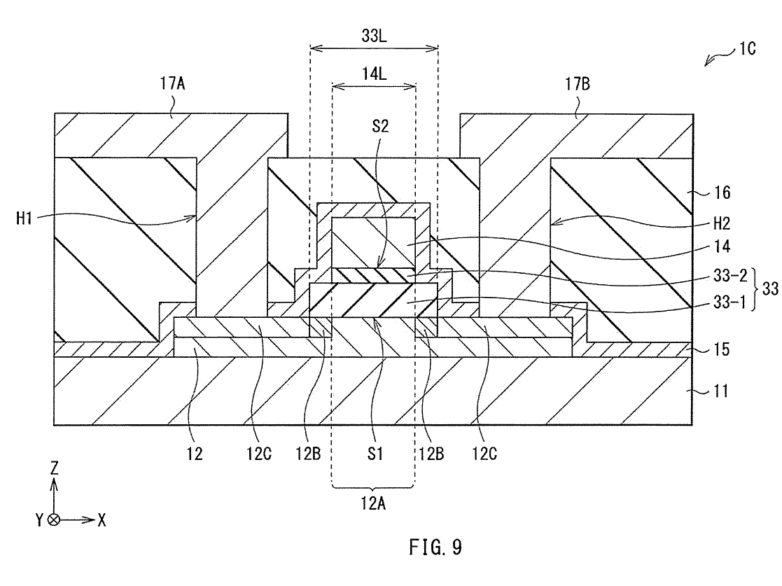

FIG. 9 illustrates a cross-sectional configuration of a transistor (a transistor 1C) according to Modification Example 3 of the foregoing first embodiment. A gate insulating film (a gate insulating film 33) of the transistor 1C may have a laminate structure. Except this point, the transistor 1C may have a configuration similar to that of the transistor 1 of the foregoing embodiment, and the function and effect thereof are also similar.

The gate insulating film 33 may have a configuration in which a gate insulating film 33-1 and a gate insulating film 33-2 are laminated in this order, for example, from a position close to the oxide semiconductor film 12. The cross-sectional shape of each of the gate insulating films 33-1 and 33-2 may be a rectangular shape, for example. In the gate insulating film 33 having such a laminate structure, the lower surface S1 thereof may be a lower surface of the lowermost layer (the gate insulating film 33-1), and the upper surface S2 thereof may be an upper surface of the topmost layer (the gate insulating film 33-2). In other words, a length 33L of the lower surface S1 of the gate insulating film 33 may be a length of the lower surface of the gate insulating film 33-1 in the channel length direction. In the transistor 1C, the length 33L of the gate insulating film 33 is greater than the maximum length 14L of the gate electrode 14 in the channel length direction.

The length of each of the upper surface and the lower surface of the gate insulating film 33-2 may be, for example, equal to the length 14L of the gate electrode 14, and may be smaller than the length 33L. Use of materials having different etching rates for the gate insulating films 33-1 and 33-2 allows for easy formation of such a gate insulating film 33. More specifically, a material having a lower etching rate may be used for the gate insulating film 33-1, and a material having a higher etching rate may be used for the gate insulating film 33-2. For example, aluminum oxide (Al₂O₃) may be used for the gate insulating film 33-1, and silicon oxide (SiO₂) may be used for the gate insulating film 33-2. The length of the gate insulating film 33-2 in the channel length direction may be the same as the length of the gate insulating film 33-1 in the channel length direction (FIG. 8), and the gate insulating film 33 may have a tapered shape (FIG. 1). The gate insulating film 33 may have a laminate structure with three layers or more.

### Second Embodiment

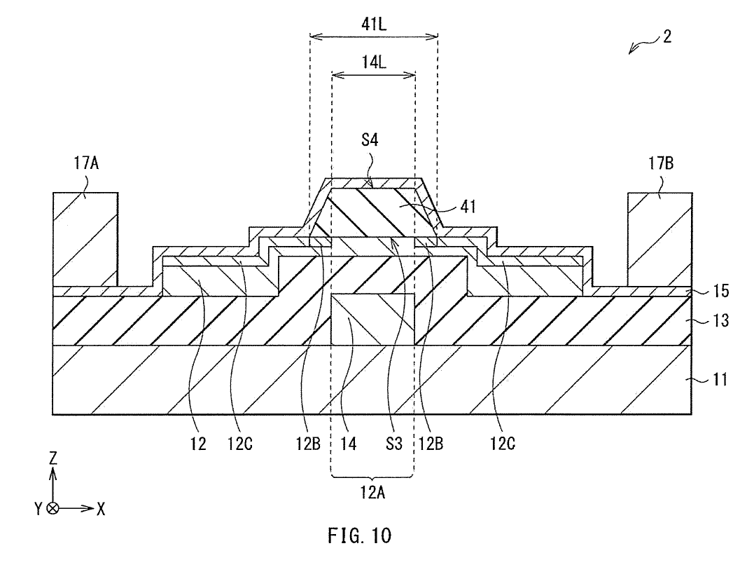

FIG. 10 illustrates a cross-sectional configuration of a transistor (a transistor 2) according to a second embodiment of the technology. The transistor 2 may have an inverted-staggered structure (bottom gate structure). Except this point, the transistor 2 may have a configuration similar to that of the transistor 1 of the foregoing embodiment, and the function and effect thereof are also similar.

The transistor 2 may have a configuration in which the gate electrode 14, the gate insulating film 13, the oxide semiconductor film 12, and an etching stopper film 41 are provided in this order on the substrate 11. The gate electrode 14, the gate insulating film 13, the oxide semiconductor film 12, and the etching stopper film 41 may be covered with the high-resistance film 15. A region, of the oxide semiconductor film 12, which faces the gate electrode 14 and is overlapped with the gate electrode 14 in a plan view may serve as the channel region 12A. On the other hand, similarly to the transistor 1, a part of a region, of the oxide semiconductor film 12, other than the channel region 12A from a surface (upper surface) in the thickness direction may serve as the diffusion region 12B and the low-resistance region 12C both having a resistance value lower than that of the channel region 12A. The low-resistance region 12C may be formed, for example, by reacting metal such as aluminum (Al) with the oxide semiconductor material to diffuse the metal (dopant). Hydrogen, instead of the metal, may be diffused to thereby form the low-resistance region 12C. The diffusion region 12B may be a region generated as a result of the diffusion of the metal such aluminum or hydrogen in the low-resistance region 12C, and may be formed at a position adjacent to the low-resistance region 12C and between the channel region 12A and the low-resistance region 12C.

The etching stopper film 41 may have a tapered shape, for example, and the cross-sectional shape of the etching stopper film 41 may be a trapezoidal shape. The etching stopper film 41 may be configured by an inorganic insulating film such as a silicon oxide film (SiOx) and an aluminum oxide film (AlOx). The etching stopper film 41 may be provided in a selective region on the oxide semiconductor film 12 so as to cover the channel region 12A. The etching stopper film 41 may have a lower surface S3 closer to the oxide semiconductor film 12 and an upper surface S4 facing the lower surface S3, and, for example, the lower surface S3 may be in contact with the oxide semiconductor film 12. In the present embodiment, a length (a length 41L) of the lower surface S3 of the etching stopper film 41 in the channel length direction (X-direction) is greater than the maximum length 14L of the gate electrode 14 in the channel length direction. In other words, the lower surface S3 of the etching stopper film 41 may be expanded in width toward both sides of the gate electrode 14 (toward the source/drain electrodes 17A and 17B) in a plan view.

The high-resistance film 15 on the etching stopper film 41 may be in contact with a region, of the oxide semiconductor film 12, other than a region in contact with the lower surface S3 of the etching stopper film 41. In other words, the low-resistance region 12C may be provided at a portion other than a region in contact with the lower surface S3 of the etching stopper film 41. On the other hand, the channel region 12A of the oxide semiconductor film 12 may be a region overlapped with the gate electrode 14 in a plan view. In this example, the length 41L of the lower surface S3 of the etching stopper film 41 in the channel length direction may be greater than the maximum length 14L of the gate electrode 14 in the channel length direction, and thus the low-resistance region 12C may be provided apart from the channel region 12A. Accordingly, metal such as aluminum contained in the low-resistance region 12C is less likely to reach the channel region 12A also in the transistor 2, similarly to the above-described transistor 1. Therefore, it becomes possible to prevent the resistance of the channel region 12A from being lowered, thus allowing for reduction in a parasitic capacitance.

### Application Example

FIG. 11 illustrates a cross-sectional configuration of a display unit (a display unit 5) including the transistor 1 as a driving device. The display unit 5 may be an active matrix organic electroluminescence (EL) display unit, and may include the plurality of transistors 1 and a plurality of organic EL devices 50A driven by the transistors 1. FIG. 11 illustrates a region (a sub-pixel) corresponding to one transistor 1 and one organic EL device 50A. FIG. 11 illustrates the display unit 5 including the transistor 1; however, the display unit 5 may also include the above-described transistor 1A, 1B, 1C, or 2 instead of the transistor 1.

The organic EL device 50A may be provided on the transistor 1 with a planarization film 19 interposed in between. The organic EL device 50A may include a first electrode 51, an inter-pixel insulating film 52, an organic layer 53, and a second electrode 54 in this order from the planarization film 19, and may be sealed by a protective layer 55. A sealing substrate 57 may be joined onto the protective layer 55 with an adhesive layer 56 made of a thermosetting resin or an ultraviolet curable resin interposed in between. The display unit 5 either may be a bottom emission display unit in which light generated in the organic layer 53 is extracted from the substrate 11 side, or may be a top emission display unit in which light generated in the organic layer 53 is extracted from the sealing substrate 57 side.

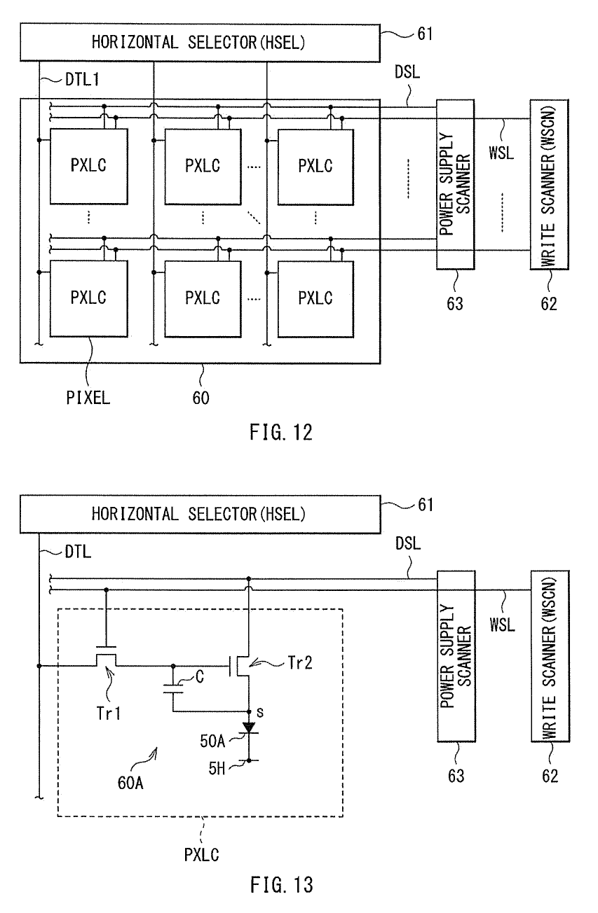

The planarization film 19 may be provided throughout the entire display region (a display region 60 in FIG. 12 described later) of the substrate 11 on the source/drain electrodes 17A and 17B and the interlayer insulating film 16, and may have a connection hole H3. The connection hole H3 may be provided for allowing the source/drain electrode 17A of the transistor 1 and the first electrode 51 of the organic EL device 50A to be coupled to each other. The planarization film 19 may be made of, for example, polyimide or an acrylic resin.

The first electrode 51 may be provided on the planarization film 19 so as to fill the connection hole H3 therewith. The first electrode 51 may function as, for example, an anode, and may be provided for each device. In a case where the display unit 5 is the bottom emission display unit, the first electrode 51 may be configured by a transparent electrically-conductive film, for example, a monolayer film made of one of indium-tin oxide (ITO), indium-zinc oxide (IZO), indium-zinc oxide (InZnO), etc., or a laminate film made of two or more of the monolayer films. On the other hand, in a case where the display unit 5 is the top emission display unit, the first electrode 51 may be configured by a monolayer film made of a metal simple substance of one of reflective metal, for example, aluminum, magnesium (Mg), calcium (Ca), and sodium (Na), or an alloy including one or more thereof, or by a multilayer film in which the metal simple substance or the alloy is laminated.

The first electrode 51 may be provided in contact with a surface of the source/drain electrode 17A (a surface closer to the organic EL device 50A). This makes it possible to eliminate the planarization film 19 as well as to reduce the number of processes for manufacturing the display unit 5.

A pixel separation film 52 may be provided to secure insulation between the first electrode 51 and the second electrode 54 and to define and separate light emission regions of respective devices from one another. The pixel separation film 52 may include respective openings facing the light emission regions of the respective devices. The pixel separation film 52 may be made of, for example, a photosensitive resin such as polyimide, an acrylic resin, or a novolac resin.

The organic layer 53 may be provided so as to cover the openings of the pixel separation film 52. The organic layer 53 may include an organic electroluminescence layer (organic EL layer), and generates light in response to application of a drive current. The organic layer 53 may include, for example, a hole injection layer, a hole transport layer, the organic EL layer, and an electron transport layer in this order from the substrate 11 (the first electrode 51), and electrons and holes are recombined in the organic EL layer to cause light emission. The material constituting the organic EL layer may be a typical low-molecular-weight material or a typical polymer material, and may not be specifically limited. For example, the organic EL layers that emit red light, green light, and blue light may be color-coded for respective devices, or organic EL layers (for example, a laminate of a red organic EL layer, a green organic EL layer, and a blue organic EL layer) that emit white light may be provided throughout the entire surface of the substrate 11. The hole injection layer may be provided for enhancing hole injection efficiency and for preventing leakage. The hole transport layer may be provided for enhancing hole transport efficiency to the organic EL layer. Layers other than the organic EL layer such as the hole injection layer, the hole transport layer, and the electron transport layer may be provided as necessary.

The second electrode 54 may function as, for example, a cathode, and may be configured by a metal electrically-conductive film. In a case where the display unit 5 is the bottom emission display unit, the second electrode 54 may be configured by a monolayer film made of a metal simple substance of one of reflective metal, for example, aluminum, magnesium (Mg), calcium (Ca), and sodium (Na), or an alloy including one or more thereof, or by a multilayer film in which the metal simple substance or the alloy is laminated. On the other hand, in a case where the display unit 5 is the top emission display unit, a transparent electrically-conductive film such as ITO and IZO may be used for the second electrode 54. For example, the second electrode 54 may be shared by the respective devices while being insulated from the first electrode 51.

The protective layer 55 may be made of either an insulating material or an electrically-conductive material. Examples of the insulating material may include amorphous silicon (a-Si), amorphous silicon carbide (a-SiC), amorphous silicon nitride (a-Si_{(1-X)}Nx), and amorphous carbon (a-C).

The sealing substrate 57 may be disposed so as to face the substrate 11 with the transistor 1 and the organic EL device 50A interposed in between. A material similar to that of the substrate 11 may be used for the sealing substrate 57. In the case where the display unit 5 is the top emission display unit, a transparent material may be used for the sealing substrate 57, and a color filter or a light-shielding film may also be provided on the sealing substrate 57 side. In the case where the display unit 5 is the bottom emission display unit, the substrate 11 may be made of a transparent material, and, for example, a color filter or a light-shielding film may be provided on the substrate 11 side.

As illustrated in FIG. 12, the display unit 5 may include a plurality of pixels PXLC each including such an organic EL device 50A, and the pixels PXLC may be arranged, for example, in matrix in a display region 60 on the substrate 11. A horizontal selector (HSEL) 61 as a signal line drive circuit, a write scanner (WSCN) 62 as a scanning line drive circuit, and a power supply scanner 63 as a power supply line drive circuit may be provided around the display region 60.

The display region 60 may include a plurality of (n-number of) signal lines DTL1 to DTLn that are arranged in a column direction, and a plurality of (m-number of) scanning lines WSL1 to WSLm that are arranged in a row direction. The pixel PXLC (one of pixels corresponding to R, G, and B) may be provided at each intersection of the signal line DTL and the scanning line WSL. Each signal line DTL may be electrically coupled to the horizontal selector 61, and an image signal may be supplied from the horizontal selector 61 to each pixel PXLC through the signal line DTL. In contrast, each scanning line WSL may be electrically coupled to the write scanner 62, and a scanning signal (a selection pulse) may be supplied from the write scanner 62 to each pixel PXLC through the scanning line WSL. Each power supply line DSL may be coupled to the power supply scanner 63, and a power supply signal (a control pulse) may be supplied from the power supply scanner 63 to each pixel PXLC through the power supply line DSL.

FIG. 13 illustrates an example of a specific circuit configuration in the pixel PXLC. Each pixel PXLC may include a pixel circuit 60A including the organic EL device 50A. The pixel circuit 60A may be an active drive circuit including a sampling transistor Tr1, a drive transistor Tr2, a capacitor C, and the organic EL device 50A. Note that one or both of the sampling transistor Tr1 and the drive transistor Tr2 may correspond to the above-described transistor 1.

The sampling transistor Tr1 may include a gate coupled to the corresponding scanning line WSL, one of a source and a drain coupled to the corresponding signal line DTL, and the other of the source and the drain coupled to a gate of the drive transistor Tr2. The drive transistor Tr2 may include a drain coupled to the corresponding power supply line DSL, and a source coupled to an anode of the organic EL device 50A. Moreover, a cathode of the organic EL device 50A may be coupled to a grounding wire 5H. Note that the grounding wire 5H is shared by all of the pixels PXLC. The capacitor C may be disposed between the source and the gate of the drive transistor Tr2.

The sampling transistor Tr1 may be brought into conduction in response to the scanning signal (selection pulse) supplied from the scanning line WSL, thereby sampling a signal potential of an image signal supplied from the signal line DTL and holding the signal potential in the capacitor C. The drive transistor Tr2 may receive a current supplied from the power supply line DSL that is set to a predetermined first potential (not illustrated), and may supply a drive current to the organic EL device 50A on a basis of the signal potential held in the capacitor C. The organic EL device 50A may emit light with luminance corresponding to the signal potential of the image signal by the drive current supplied from the drive transistor Tr2.

In such a circuit configuration, the signal potential of the image signal supplied from the signal line DTL may be sampled by bringing the sampling transistor Tr1 into conduction in response to the scanning signal (selection pulse) supplied from the scanning line WSL to be held in the capacitor C. Moreover, the current may be supplied from the power supply line DSL that is set to the above-described first potential to the drive transistor Tr2, and the drive current may be supplied to the organic EL device 50A (each of the organic EL devices of red, green, and blue) on a basis of the signal potential held in the capacitor C. Thereafter, each organic EL device 50A may emit light with luminance corresponding to the signal potential of the image signal by the supplied drive current. Thus, the display unit 5 may display an image on the basis of the image signal.

Such a display unit 5 is formed, for example, as follows.

First, as described above, the transistor 1 may be formed. Subsequently, the planarization film 19 made of the above-described material may be formed by means of, for example, a spin coating method or a slit coating method so as to cover the interlayer insulating film 16, and the source/drain electrodes 17A and 17B, and the connection hole H3 may be formed in a part of a region facing a source electrode 17.

Subsequently, the organic EL device 50A may be formed on the planarization film 19. More specifically, the first electrode 51 made of the above-described material may be formed on the planarization film 19 by means of, for example, a spluttering method so as to fill the connection hole H3 therewith, following which patterning may be performed on the first electrode 51 by means of photolithography and etching. Thereafter, the pixel separation film 52 having openings may be formed on the first electrode 51, and then the organic layer 53 may be formed by means of, for example, a vacuum deposition method. Subsequently, the second electrode 54 made of the above-described material may be formed on the organic layer 53 by means of, for example, the sputtering method. Subsequently, the protective layer may be formed on the second electrode 54 by means of, for example, the CVD method, following which the sealing substrate 57 may be joined onto the protective layer using the adhesive layer 56. Thus, the display unit 5 illustrated in FIG. 11 is completed.

In the display unit 5, for example, when a drive current corresponding to an image signal of each color is applied to each pixel PXLC corresponding to one of R, G, and B, electrons and holes are injected into the organic layer 53 through the first electrode 51 and the second electrode 54. The electrons and the holes are recombined in the organic EL layer included in the organic layer 53 to cause light emission. Thus, in the display unit 5, for example, a full-color image of R, G, and B may be displayed. Moreover, a charge corresponding to the image signal may be accumulated in the capacitor C by applying a potential corresponding to the image signal to an end of the capacitor C upon the image display operation.

In this case, the display unit 5 may include the transistor 1 with a reduced parasitic capacitance, and thus the driving speed of the display unit 5 may be improved.

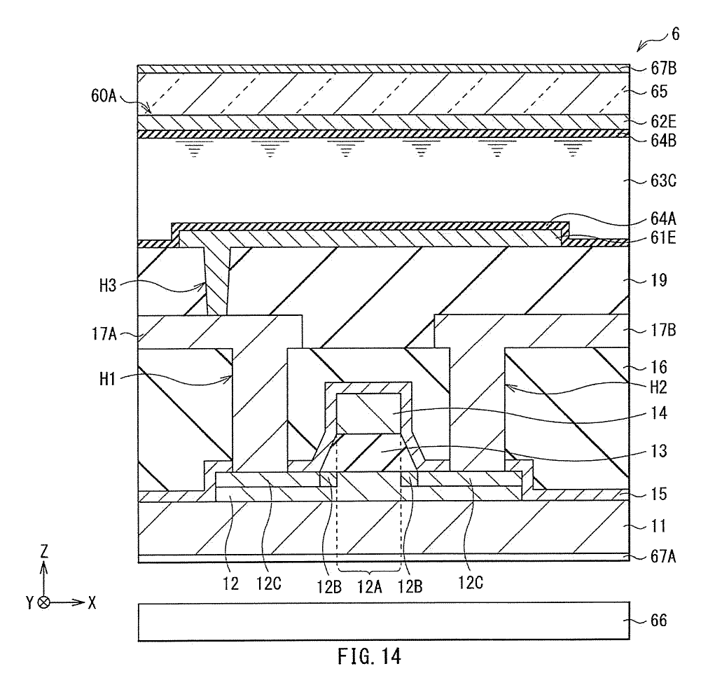

As illustrated in FIG. 14, the transistor 1 (or one of the transistors 1A, 1B, 1C, and 2) may also be applied to a display unit (a display unit 6) including a liquid crystal display device (a liquid crystal display device 60A). The display unit 6 may include the liquid crystal display device 60A in a layer above the transistor 1.

The liquid crystal display device 60A may have a configuration, for example, in which a liquid crystal layer 63C is sealed between a pixel electrode 61E and a counter electrode 62E. Orientation films 64A and 64B may be provided, respectively, on surfaces of the pixel electrode 61E and the counter electrode 62E both on the liquid crystal layer 63C side. The pixel electrode 61E may be provided for each pixel, and may be electrically coupled to, for example, the source/drain electrode 17A of the transistor 1. The counter electrode 62E may be provided on a counter substrate 65 as a common electrode shared by the plurality of pixels, and may be held at, for example, a common potential. The liquid crystal layer 63C may be configured by liquid crystal driven in, for example, a vertical alignment (VA) mode, a twisted nematic (TN) mode, an in plane switching (IPS) mode, or other modes.

Moreover, a backlight 66 may be disposed below the substrate 11. Polarizing plates 67A and 67B may be joined, respectively, to the substrate 11 on the backlight 66 side and the counter substrate 65.

The backlight 66 may be a light source that emits light toward the liquid crystal layer 63C, and may include, for example, a plurality of light emitting diodes (LED) or cold cathode fluorescent lamps (CCFL). The backlight 66 may be controlled between a lighting-on state and a lighting-off state by an unillustrated backlight drive section.

The polarizing plates 67A and 67B (polarizer, analyzer) may be disposed, for example, in crossed Nicols to each other, thus allowing illumination light emitted from the backlight 66, for example, to be blocked in no-voltage-applied state (an OFF state) and to pass through in a voltage-applied state (an ON state).

Similarly to the display unit 5, the display unit 6 may include the transistor 1 with a reduced parasitic capacitance, and thus the driving speed of the display unit 6 may be improved.

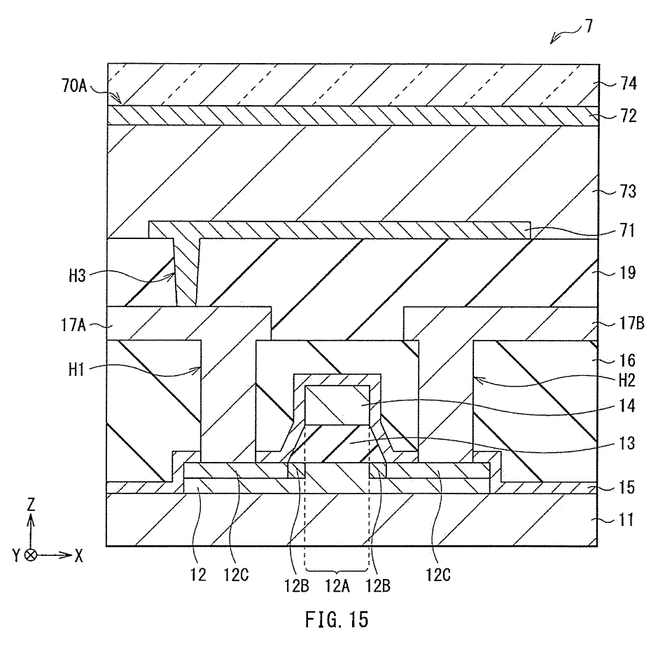

As illustrated in FIG. 15, the transistor 1 (or one of the transistors 1A, 1B, 1C, and 2) may also be applied to a display unit (a display unit 7) including an electrophoresis display device (an electrophoresis display device 70A). The display unit 7 may include the electrophoresis display device 70A in a layer above the transistor 1.

The electrophoresis display device 70A may have a configuration, for example, in which a display layer 73 configured by an electrophoresis display body is sealed between a pixel electrode 71 and a common electrode 72. The pixel electrode 71 may be disposed for each pixel, and may be coupled electrically to the source/drain electrode 17A of the transistor 1, for example. The common electrode 72 may be provided on a counter substrate 74 as a common electrode shared by a plurality of pixels.

Similarly to the display unit 5, the display unit 7 may include the transistor 1 with a reduced parasitic capacitance, and thus the driving speed of the display unit 7 may be improved.

The display units 5, 6, and 7 are applicable to electronic apparatuses in every field that display, as an image or a picture, an image signal received from outside or an image signal generated inside. Examples of the electronic apparatuses may include televisions, digital cameras, laptop personal computers, mobile terminals such as mobile phones, and video cameras.

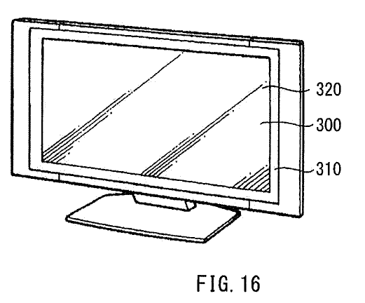

FIG. 16 illustrates an outer appearance of a television to which any of the display units 5, 6, and 7 is applicable. The television may have an image display screen section 300 including a front panel 310 and a filter glass 320, for example. The image display screen section 300 may be configured by any of the above-described display units 5, 6, and 7.

Although description has been given heretofore with reference to the embodiments and the modification examples, the technology is by no means limited to the foregoing embodiments and the modification examples, and various modifications are possible. For example, although the description has been given, in the foregoing embodiments and the modification examples, of the example of the structure in which the high-resistance film 15 is provided, the high-resistance film 15 may also be removed after the formation of the low-resistance region 12C. However, it is desirable that the high-resistance film 15 be provided, since providing the high-resistance film 15 enables the electrical characteristics of the transistor to be stably held as described above.

Further, although the description has been given, in the foregoing embodiments and the modification examples, of the case where the low-resistance region 12C is provided in a part of the oxide semiconductor film 12 in the thickness direction from the surface (upper surface) thereof, the low-resistance region 12C may also be provided in the entire region of the oxide semiconductor film 12 in the thickness direction from the surface (upper surface) thereof.

Furthermore, for example, the material and the thickness of each of the layers, or the film-forming method and the film-forming condition described in the foregoing embodiments and the modification examples are not limited, and other materials and other thicknesses, or other film-forming methods and other film-forming conditions may also be adopted.

In addition, although description has been given, referring to the example of the display unit as an application example of the transistor in the foregoing embodiments and the modification examples, the transistor may also be applicable to an image detector or other units.

Note that the effects described in the present specification are merely illustrative and non-limiting, and may be effects other than those described above.

Note that an embodiment of the technology may have the following configurations.

(1)
A transistor including:
a gate electrode;
an oxide semiconductor film including a channel region and a low-resistance region, the channel region facing the gate electrode, the low-resistance region having a resistance value lower than a resistance value of the channel region; and
a gate insulating film provided between the oxide semiconductor film and the gate electrode, and having a first surface located closer to the oxide semiconductor film and a second surface located closer to the gate electrode, the first surface of the gate insulating film having a length in a channel length direction which is greater than a maximum length of the gate electrode in the channel length direction.
   (2)
The transistor according to (1), wherein
the oxide semiconductor film, the gate insulating film, and the gate electrode are provided in this order on a substrate, and
the first surface of the gate insulating film is in contact with the oxide semiconductor film.
   (3)
The transistor according to (1) or (2), wherein the low-resistance region of the oxide semiconductor film contains a metal.
   (4)
The transistor according to (3), wherein the oxide semiconductor film includes a diffusion region located adjacent to the low-resistance region and between the channel region and the low-resistance region.
   (5)
The transistor according to (4), wherein the diffusion region contains the metal at a concentration lower than a concentration of the metal in the low-resistance region.
   (6)
The transistor according to (5), wherein the concentration of the metal in the diffusion region becomes lower toward a position closer to the channel region from a position closer to the low-resistance region.
   (7)
The transistor according to any one of (4) to (6), wherein the diffusion region is provided in a part of a region, of the oxide semiconductor film, overlapped with the gate insulating film in a plan view.
   (8)
The transistor according to any one of (1) to (7), further including a source/drain electrode electrically coupled to the low-resistance region of the oxide semiconductor film.
   (9)
The transistor according to any one of (1) to (8), further including a high-resistance film provided in contact with the low-resistance region.
   (10)
The transistor according to (9), wherein the high-resistance film contains a metal oxide.
   (11)
The transistor according to any one of (1) to (10), wherein the oxide semiconductor film contains indium.
   (12)
The transistor according to any one of (1) to (11), wherein the second surface of the gate insulating film has a length in the channel length direction which is smaller than the length of the first surface of the gate insulating film in the channel length direction.
   (13)
The transistor according to any one of (1) to (11), wherein the second surface of the gate insulating film has a length in the channel length direction which is equal to the length of the first surface of the gate insulating film in the channel length direction.
   (14)
The transistor according to any one of (1) to (13), wherein the gate insulating film has a laminate structure.
   (15)
The transistor according to any one of (1) to (14), wherein the gate electrode has a tapered shape.
   (16)
A transistor including:
a gate electrode; and
an oxide semiconductor film including a channel region and a low-resistance region, the channel region facing the gate electrode, the low-resistance region being provided apart from the channel region and having a resistance value lower than a resistance value of the channel region.
   (17)
The transistor according to (16), further including:
a gate insulating film provided between the gate electrode and the oxide semiconductor film; and
an etching stopper film, wherein
the gate electrode, the gate insulating film, the oxide semiconductor film, and the etching stopper film are provided in this order on a substrate, and
a length of a surface, of the etching stopper film, closer to the oxide semiconductor film in a channel length direction is greater than a maximum length of the gate electrode in the channel length direction.
   (18)
The transistor according to (16) or (17), wherein the oxide semiconductor film includes a diffusion region located adjacent to the low-resistance region and between the channel region and the low-resistance region.
   (19)
A display unit including a display device and a transistor that drives the display device, the transistor including:
a gate electrode;
an oxide semiconductor film including a channel region and a low-resistance region, the channel region facing the gate electrode, the low-resistance region having a resistance value lower than a resistance value of the channel region; and
a gate insulating film provided between the oxide semiconductor film and the gate electrode, and having a first surface located closer to the oxide semiconductor film and a second surface located closer to the gate electrode, the first surface of the gate insulating film having a length in a channel length direction which is greater than a maximum length of the gate electrode in the channel length direction.
   (20)
An electronic apparatus provided with a display unit, the display unit including a display device and a transistor that drives the display device, the transistor including:
a gate electrode;
an oxide semiconductor film including a channel region and a low-resistance region, the channel region facing the gate electrode, the low-resistance region having a resistance value lower than a resistance value of the channel region; and
a gate insulating film provided between the oxide semiconductor film and the gate electrode, and having a first surface located closer to the oxide semiconductor film and a second surface located closer to the gate electrode, the first surface of the gate insulating film having a length in a channel length direction which is greater than a maximum length of the gate electrode in the channel length direction.

Although the technology has been described in terms of exemplary embodiments, it is not limited thereto. It should be appreciated that variations may be made in the described embodiments by persons skilled in the art without departing from the scope of the technology as defined by the following claims. The limitations in the claims are to be interpreted broadly based on the language employed in the claims and not limited to examples described in this specification or during the prosecution of the application, and the examples are to be construed as non-exclusive. For example, in this disclosure, the term “preferably” or the like is non-exclusive and means “preferably”, but not limited to. The use of the terms first, second, etc. do not denote any order or importance, but rather the terms first, second, etc. are used to distinguish one element from another. The term “about” as used herein can allow for a degree of variability in a value or range. Moreover, no element or component in this disclosure is intended to be dedicated to the public regardless of whether the element or component is explicitly recited in the following claims.

What is claimed is:

1. A transistor comprising:
a gate electrode;
an oxide semiconductor film including a channel region and a low-resistance region, the channel region facing the gate electrode, the low-resistance region having a resistance value lower than a resistance value of the channel region; and
a gate insulating film provided between the oxide semiconductor film and the gate electrode, and having a first surface located closer to the oxide semiconductor film and a second surface located closer to the gate electrode, wherein:
the first surface of the gate insulating film has a first length in a channel length direction which is greater than a maximum length of the gate electrode in the channel length direction, and
the gate insulating film has a laminate structure.

2. The transistor according to claim 1, wherein
the oxide semiconductor film, the gate insulating film, and the gate electrode are provided in this order on a substrate, and
the first surface of the gate insulating film is in contact with the oxide semiconductor film.

3. The transistor according to claim 1, wherein the low-resistance region of the oxide semiconductor film contains a metal.

4. The transistor according to claim 3, wherein the oxide semiconductor film includes a diffusion region located adjacent to the low-resistance region and between the channel region and the low-resistance region.

5. The transistor according to claim 4, wherein the diffusion region contains the metal at a concentration lower than a concentration of the metal in the low-resistance region.

6. The transistor according to claim 5, wherein the concentration of the metal in the diffusion region becomes lower toward a position closer to the channel region from a position closer to the low-resistance region.

7. The transistor according to claim 4, wherein the diffusion region is provided in a part of a region, of the oxide semiconductor film, overlapped with the gate insulating film in a plan view.

8. The transistor according to claim 1, further comprising a source/drain electrode electrically coupled to the low-resistance region of the oxide semiconductor film.

9. The transistor according to claim 1, further comprising a high-resistance film provided in contact with the low-resistance region.

10. The transistor according to claim 9, wherein the high-resistance film contains a metal oxide.

11. The transistor according to claim 1, wherein the oxide semiconductor film contains indium.

12. The transistor according to claim 1, wherein the second surface of the gate insulating film has a length in the channel length direction which is smaller than the first length of the first surface of the gate insulating film in the channel length direction.

13. The transistor according to claim 1, wherein the second surface of the gate insulating film has a length in the channel length direction which is equal to the first length of the first surface of the gate insulating film in the channel length direction.

14. The transistor according to claim 1, wherein the gate electrode has a tapered shape.

15. A display unit including a display device and a transistor that drives the display device, the transistor comprising:
a gate electrode;
an oxide semiconductor film including a channel region and a low-resistance region, the channel region facing the gate electrode, the low-resistance region having a resistance value lower than a resistance value of the channel region; and
a gate insulating film provided between the oxide semiconductor film and the gate electrode, and having a first surface located closer to the oxide semiconductor film and a second surface located closer to the gate electrode, wherein:
the first surface of the gate insulating film has a first length in a channel length direction which is greater than a maximum length of the gate electrode in the channel length direction, and
the gate insulating film has a laminate structure.

16. An electronic apparatus provided with a display unit, the display unit including a display device and a transistor that drives the display device, the transistor comprising:
a gate electrode;
an oxide semiconductor film including a channel region and a low-resistance region, the channel region facing the gate electrode, the low-resistance region having a resistance value lower than a resistance value of the channel region; and
a gate insulating film provided between the oxide semiconductor film and the gate electrode, and having a first surface located closer to the oxide semiconductor film and a second surface located closer to the gate electrode, wherein:
the first surface of the gate insulating film has a first length in a channel length direction which is greater than a maximum length of the gate electrode in the channel length direction, and
the gate insulating film has a laminate structure.
